(19) United States
(12) Patent Application Publication
(10) Pub. No.: US 2007/0166985 A1
(43) Pub. Date: Jul. 19, 2007

(54) Fabrication Method of Thin Film and Metal Line in Semiconductor Device

(76) Inventor: Han Choon Lee, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/614,101

(22) Filed: Dec. 21, 2006

(30) Foreign Application Priority Data
Dec. 29, 2005 (KR) 10-2005-0134362

(51) Int. Cl. H01L 21/44

(52) U.S. Cl. 438/597

(57) ABSTRACT

A method for fabricating a thin layer in a semiconductor device is provided. The method can include: forming a preliminary layer, in which Ta and F are mixed, on a semiconductor substate by performing an Atomic Layer Deposition (ALD) method; forming a Ta layer by reacting the preliminary layer with B₂H₆; and forming a TaN layer by performing heat treatment for the Ta layer in N₂ atmosphere.

### RELATED APPLICATION(S)

This application claims priority under 35 U.S.C. §119(e) of Korean Patent Application No. 10-2005-0134362 filed Dec. 29, 2005, which is incorporated herein by reference in its entirety.

### FIELD OF THE INVENTION

The present invention relates to a method for fabricating a metal wiring in a semiconductor device, and more particularly to a semiconductor device including a copper wiring.

### BACKGROUND OF THE INVENTION

With the gradual high speed and high integration of a semiconductor device, the metal wiring formed in the semiconductor device becomes finer and dual layered. Since the width of the metal wiring becomes narrower as described above, signal delay occurs due to the resistance and capacitance of the metal wiring. In order to reduce the signal delay, metal (e.g. copper) with low resistance has been used.

However, copper is not as easily etched as compared to the metal (e.g. aluminum) used in the prior art. On account of this, in order to form a copper wiring, a trench is formed in a dielectric layer and then filled with copper. Next, the copper wiring is formed through a damascene process in which chemical and mechanical polishing is carried out on the semiconductor substrate.

However, since copper easily diffuses into another layer, the trench is filled with the copper after a barrier layer is formed.

The barrier layer may be made from Ta (tantalum), but Ta does not completely prevent the diffusion of the copper.

In order to solve this, the barrier layer tends to be made from TaN (tantalumn nitride).

Although the TaN layer is better at preventing the diffusion of the copper as compared to the Ta layer, TaN has poor adhesion with copper.

Accordingly, the barrier layer is made from a dual layer such as TaN/Ta so as to improve the reliability of a device. Such a dual barrier layer may be formed through a Physical Vapor Deposition (PVD) method or an Atomic Layer Deposition (ALD) method.

If the dual barrier layer is formed through the PVD method, overhanging occurs, which blocks the entrance of a via when the aspect ratio of the via increases. Therefore, the barrier layer is not uniformly formed. If the dual barrier layer is formed through the ALD method, different precursors are typically used when forming TaN and Ta. Therefore, the process becomes complicated.

### BRIEF SUMMARY

Accordingly, embodiments of the present invention are directed to a method for fabricating a metal wiring in a semiconductor device that substantially obviates one or more problems due to limitations and disadvantages of the related art.

An object of the present invention is to provide a method for easily forming a TaN/Ta layer while preventing overhanging from occurring.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

In accordance with one embodiment of the present invention, there is provided a method for fabricating a thin layer in a semiconductor device, the method comprising: forming a preliminary layer, in which Ta and F are mixed, on a semiconductor substrate through an Atomic Layer Deposition (ALD) method; forming a Ta layer through reaction of the preliminary layer and B₂H₆; and forming a TaN layer by performing heat treatment for the Ta layer in N₂ atmosphere.

In a preferred embodiment, the preliminary layer can be formed to have a thickness of 0.5 Å to 10 Å.

In a further preferred embodiment, the preliminary layer can be formed during which the temperature of the semiconductor substrate is maintained to be in the range of 100° C. to 500° C.

In accordance with another embodiment of the present invention, there is provided a method for fabricating a metal wiring in a semiconductor device, the method comprising: forming an interlayer dielectric on a semiconductor substrate; forming a trench in the interlayer dielectric by performing a selective etching process; forming a first preliminary layer, in which Ta and F are mixed, on the semiconductor substrate including the trench through an Atomic Layer Deposition (ALD) method; forming a first Ta layer through reaction of the first preliminary layer and B₂H₆; forming a TaN layer by performing heat treatment for the first Ta layer in N₂ atmosphere; forming a second preliminary layer, in which Ta and F are mixed, on the TaN layer through an ALD method; forming a second Ta layer through reaction of the second preliminary layer and B₂H₆; and forming a metal wiring on the second Ta layer.

In a preferred embodiment, the preliminary layer can be formed to have a thickness of 0.5 Å to 10 Å.

In addition, the TaN layer and the second Ta layer can be formed to have a thickness of 10 Å to 300 Å.

In a further preferred embodiment, the preliminary layers can be formed during which the temperature of the semiconductor substrate is maintained to be in the range of 100° C. to 500° C.

The metal wiring can be made from copper.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIG. 1 is a sectional view illustrating a metal wiring in a semiconductor device according to an embodiment of the present invention.

FIGS. 2 to 4 are sectional views illustrating a method for fabricating a metal wiring in a semiconductor device based on an embodiment of the present invention.

FIG. 5 is a sectional view illustrating a metal wiring in a semiconductor device according to another embodiment of the present invention.

FIGS. 6 to 9 are sectional views illustrating a method for fabricating a metal wiring in a semiconductor device based on another embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, embodiments of the present invention will be described in detail with reference to the accompanying drawings so that those skilled in the art can easily embody the present invention. However, the present invention can be realized in various ways, and are not limited to the embodiments described herein.

Hereinafter, a metal wiring in a semiconductor device and a method for fabricating the same according to an embodiment of the present invention will be described with reference to the accompanying drawings.

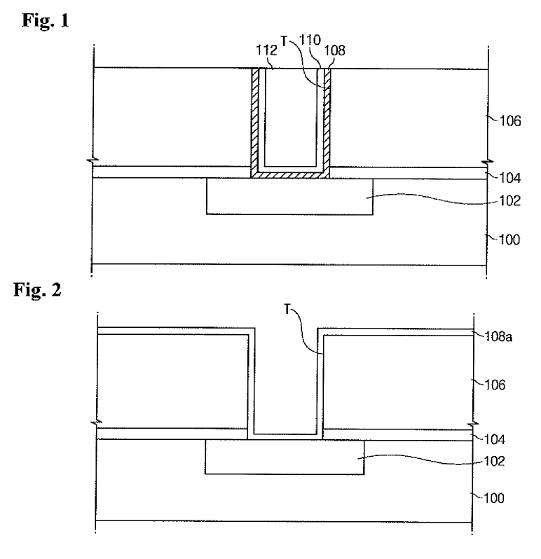

FIG. 1 is a sectional view illustrating a metal wiring in a semiconductor device according to one embodiment of the present invention.

Referring to FIG. 1, an etch stop layer 104 and an interlayer dielectric 106 can be formed on a substrate 100. The substrate 100 may include a separate device (not shown) or a lower conductor 102.

The lower conductor 102 may be made from copper (Cu), aluminum (Al), tungsten (W), silver (Ag), Gold (Au), platinum (Pt), etc. The etch stop layer 104 may be made from SiN, SiH₄, etc. The interlayer dielectric 106 may be formed by depositing an inorganic insulator or an organic insulator such as Fluorine Silicate Glass (FSG), Undoped Silicate Glass (USG), SiH₄, or Tetra Ethyl Ortho Silicate (TEOS) in a single layer or a dual layer. Further, the interlayer dielectric 106 may also be formed by using material (e.g. black diamond) with low permittivity of less than 3.0.

A trench T exposing the lower conductor 102 can be formed in the etch stop layer 104 and the interlayer dielectric 106.

In the trench T, barrier layers 108 and 110 and a metal wiring 112 can be formed, which are electrically connected to the lower conductor 102. The barrier layers 108 and 110 can be thinly formed along the inner wall of the trench T, and the metal wiring 112 can be made from a metal layer filling the trench defined by the barrier layers 108 and 110.

The barrier layers 108 and 1 0 prevent the metal material of the metal wiring 1 12 from being diffused to another layer such as an insulating layer, and elevate adhesion between an insulating layer and the metal wiring 112.

The barrier layers 108 and 110 are a dual layer, i.e. a first barrier layer 108 and a second barrier layer 110. The first barrier layer 108 can be TaN and the second barrier layer 110 can be Ta. The metal wiring 112 can be a conductive material, e.g. copper (metal with low resistance).

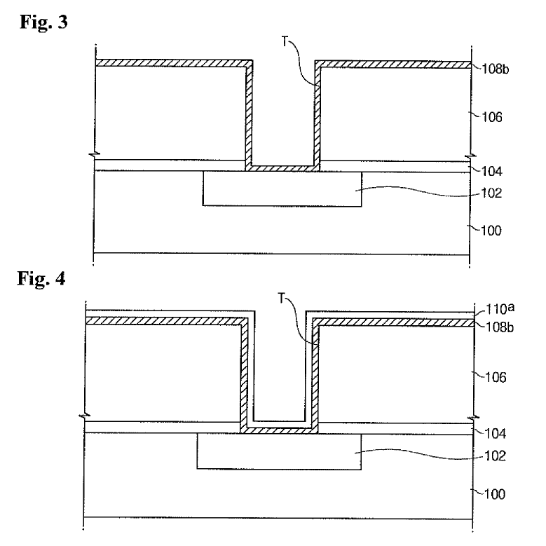

Hereinafter, a method for fabricating the metal wiring in the semiconductor device according to an embodiment of the present invention as described above will be described with reference to FIGS. 2 to 4.

FIGS. 2 to 4 are sectional views illustrating a method for fabricating a metal wiring in a semiconductor device based on an embodiment of the present invention.

Referring to FIG. 2, an etch stop layer 104 and an interlayer dielectric 106 can be deposited on a substrate 100.

A trench T exposing the etch stop layer 104 can be formed in the interlayer dielectric 106 through a selective etching process using a photoresist layer (not shown).

Then, the exposed etch stop layer 104 can be removed to expose, for example, a lower conductor 102. Next, a first preliminary layer 108a can be formed through an ALD method.

In one embodiment, the preliminary layer 108a may be formed through the following method.

First, the temperature of the substrate 100 can be maintained in the range of 100° C. to 500° C. and TaF can be injected into an ALD apparatus as the reactive gas.

In this way, the preliminary layer 108a can be formed along the inner walls of a via V and/or a trench T. The preliminary layer OSa is not a compound obtained through the reaction of Ta and F, but, rather, it is a layer in which Ta (tantalum) and F (fluorine) are mixed. Next, B₂H₆ gases can be injected in the chamber to react with the F of the preliminary layer 10a, so that the F (fluorine) is removed. Accordingly, the preliminary layer 108a is made only of the Ta. In a specific embodiment, the preliminary layer 108a can have a thickness of 0.5 Å to 10 Å.

Referring to FIG. 3, the substrate 100 can be subjected to a heat treatment in N₂ atmosphere. Then, the Ta of the preliminary layer 108a changes into TaN through a reaction with the N₂. In this way, a first barrier layer 108b made from TaN can be completed.

The process in which the preliminary layer 108a is formed using TaF and the first barrier layer 108b is formed using B₂H₆ can be repeated several times so that the first barrier layer 108b with a desired thickness can be formed. In a preferred embodiment, the first barrier layer 108b can be formed to have a thickness of 10 Å to 300 Å.

Referring to FIG. 4, a second preliminary layer 110a can be formed on the first barrier layer 108h through an ALD method. A method for forming the second preliminary layer 110a can be similar to the method for forming the preliminary layer 108a.

First, the temperature of the substrate 100 can be maintained in the range of 100° C. to 500° C. and TaF can be injected into an ALD apparatus as the reactive gases.

In this way, the second preliminary layer can be formed in a via V and/or a trench T. The second preliminary layer is not a compound obtained through the reaction of Ta and F, but, rather, it is a layer in which Ta and F are mixed. Next, B₂H₆ gases can be injected in the chamber to react with the F of the second preliminary layer, so that the F is removed. Accordingly, the second preliminary layer 110a is made only of the Ta, and can have a thickness of 0.5 Å to 10 Å.

The process in which TaF is injected to form the second preliminary layer and B₂H₆ is injected to form the second barrier layer 110a can be repeated several times, so that the second barrier layer 110a with a desired thickness is formed. In a preferred embodiment, the second barrier layer 110a can be formed to have a thickness of 10 Å to 300 Å.

Referring back to FIG. 1, copper can be formed on the second barrier layer 110a to fill the trench. Then, planarization by chemical and mechanical polishing can be performed to complete the metal wiring 112.

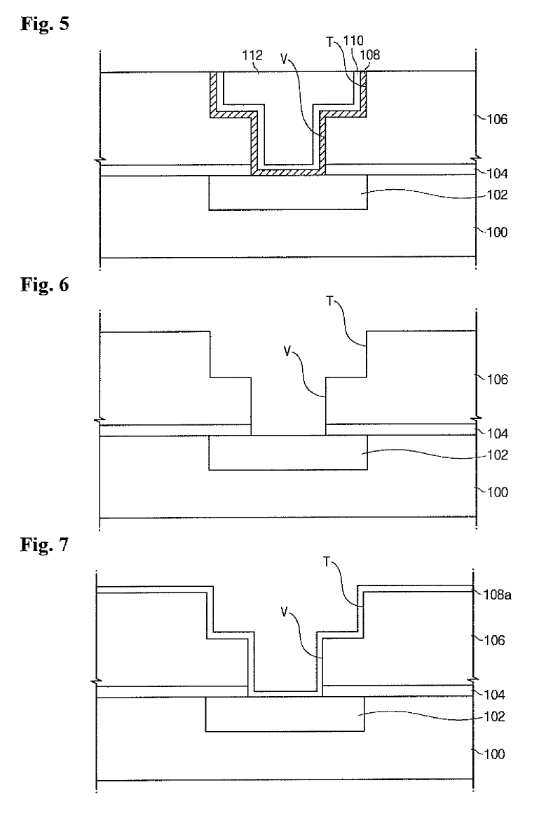

FIG. 5 is a sectional view illustrating a metal wiring in a semiconductor device according to another embodiment of the present invention.

Referring to FIG. 5, an etch stop layer 104 and an interlayer dielectric 106 can be deposited on a substrate 100. The substrate 100 may include a separate device (not shown) or a lower conductor 102.

The lower conductor 102 may be made from copper (Cu), aluminum (Al), tungsten (W), silver (Ag), Gold (Au), platinum (Pt), etc. The etch stop layer 104 may be made from SiN, SiH₄, etc. The interlayer dielectric 106 may be formed by depositing an inorganic insulator or an organic insulator such as a FSG, an USG, SiH₄, or a TEOS in a single layer or a dual layer. Further, the interlayer dielectric 106 may also be formed by using material (e.g. black diamond) with low permittivity of less than 3.0.

A via V exposing the lower conductor 102 can be formed in the etch stop layer 104 and the interlayer dielectric 106. A trench T exposing the via V can be formed in the interlayer dielectric 106.

In the trench T and the via V, barrier layers 108 and 110 and a metal wiring 112 can be formed, which are electrically connected to the lower conductor 102. The barrier layers 108 and 100 can be thinly formed along the inner walls of the via V and the trench T, and the metal wiring 112 is made from a metal layer filling the via and the trench defined by the barrier layers 108 and 110.

The barrier layers 108 and 110 prevent the metal material of the metal wiring 112 from being diffused to another layer such as an insulating layer, and elevate adhesion between an insulating layer and the metal wiring 112.

The barrier layers 108 and 110 can be a dual layer, i.e. a first barrier layer 108 and a second barrier layer 110. The first barrier layer 108 can be formed of TaN and the second barrier layer 110 can be formed of Ta. The metal wiring 112 can be a conductive material, e.g. copper (metal with low resistance).

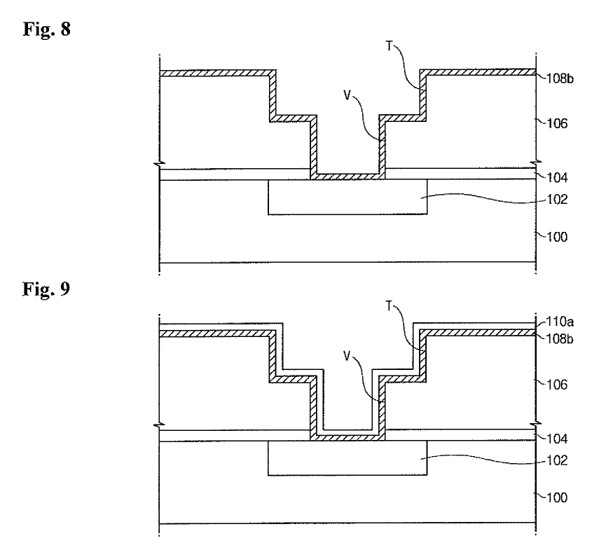

Hereinafter, a method for fabricating the metal wiring in the semiconductor device according to an embodiment of the present invention as described above will be described with reference to FIGS. 6 to 9.

FIGS. 6 to 9 are sectional views illustrating a method for fabricating a metal wiring in a semiconductor device based on an embodiment of the present invention.

Referring to FIG. 6, an etch stop layer 104 and an interlayer dielectric 106 can be deposited on the substrate 100.

The via V exposing the etch stop layer can be formed in the interlayer dielectric 106 through a selective etching process using a photoresist layer (not shown). The trench T exposing the via V can be formed through the selective etching process using a photoresist layer (not shown). In the case of forming the interlayer dielectric 106 as a dual layer, one layer of the interlayer diectric 106 can be used as an etch stop layer when forming the trench T.

Referring to FIG. 7, the exposed etch stop layer 104 can be removed to expose the lower conductor 102. Then, a first preliminary layer 108a can be formed through an ALD method.

The preliminary layer 108a may be formed through the following method.

First, the temperature of the substrate 100 can be maintained in the range of 100° C. and 500° C. and TaF can be injected into an ALD apparatus as the reactive gases.

In this way, the preliminary layer 108a can be formed along the inner walls of the via V and the trench T. The preliminary layer 108a is not a compound obtained through the reaction of Ta and F. Rather, it is a layer in which Ta and F are mixed. Next, B₂H₆ gases can be injected in the chamber for reacting with the F of the preliminary layer 108a, so that the F is removed. Accordingly, the preliminary layer 108a can be made only of the Ta. In a specific embodiment, the preliminary layer can have a thickness of 0.5 Å to 10 Å.

Referring to FIG. 8, the substrate 100 can be subjected to a heat treatment in N₂ atmosphere such that the Ta of the preliminary layer 108a changes into TaN through reaction with the N₂. In this way, a first barrier layer 108b made from TaN can be completed.

The process in which the preliminary layer 108a is formed using TaF and the first barrier layer 108b is formed using B₂H₆ can be repeated several times, so that the first barrier layer 108b with a desired thickness can be formed. In a preferred embodiment, the first barrier layer 108b can be formed to have a thickness of 10 Å to 300 Å.

Referring to FIG. 9, a second preliminary layer can be formed on the first barrier layer 108b through the ALD method. The method for forming the second preliminary layer is similar to the method for forming the preliminary layer 108a.

First, the temperature of the substrate 100 can be maintained in the range of 100° C. to 500° C. and TaF can be injected into an ALD apparatus as the reactive gases.

In this way, the second preliminary layer can be formed in the via V and the trench T. The second preliminary layer is not a compound obtained through the reaction of Ta and F, but, rather, it is a layer in which Ta and F are mixed. Next, B₂H₆ gases can be injected in the chamber to react with the F of the second preliminary layer, so that the F is removed. Accordingly, the second preliminary layer can be made only of the Ta, and can have a thickness of 0.5 Å to 10 Å.

The process in which TaF is injected to form the second preliminary layer and B₂H₆ is injected to form the second barrier layer 110a can be repeated several times, so that the second barrier layer 110a with a desired thickness is formed. In a preferred embodiment, the second barrier layer 110a can be formed to have a thickness of 10 Å to 300 Å.

Referring back to FIG. 5, a copper layer filling the trench and the via through the deposition of copper can be formed on the second barrier layer 110a. Further, the barrier layers 108 and 110 and the metal wiring 112 can be completed through a planarization process by chemical and mechanical polishing.

By using the ALD method as described above, a thin layer can be formed. Accordingly, a barrier layer not affected by a step difference can be formed, and thus the reliability of a device can be improved. In addition, a dual layer of TaN/Ta is easily formed using the same reaction gasses, so that a process can be simplified.

It will be apparent to those skilled in the art that various modifications and variations can be made in the present invention. Thus, it is intended that the present invention covers the modifications and variations of the invention provided they come within the scope of the appended claims and their equivalents.

I claim:

1. A method for fabricating a thin layer in a semiconductor device, comprising:
forming a preliminary layer, in which Ta and F are mixed, on a semiconductor substrate by performing an Atomic Layer Deposition (ALD) method;
forming a Ta layer by reacting the preliminary layer with B₂H₆; and
forming a TaN layer by performing a heat treatment for the Ta layer in N₂ atmosphere.

2. The method according to claim 1, wherein the preliminary layer is formed to have a thickness of 0.5 Å to 10 Å.

3. The method according to claim 1, wherein forming the preliminary layer comprises maintaining a temperature of the semiconductor substrate in the range of 100° C. to 500° C.

4. A method for fabricating a metal wiring in a semiconductor device, comprising:
forming an interlayer dielectric on a semiconductor substrate;
forming a trench in the interlayer dielectric by performing a selective etching process;
forming a first preliminary layer, in which Ta and F are mixed, on the semiconductor substrate including the trench by performing an Atomic Layer Deposition (ALD) method;
forming a first Ta layer by reacting the first preliminary layer with B₂H₆;
forming a TaN layer by performing a heat treatment for the first Ta layer in N₂ atmosphere;
forming a second preliminary layer, in which Ta and F are mixed, on the TaN layer by performing the ALD method;
forming a second Ta layer by reacting the second preliminary layer with B₂H₆; and
forming a metal wiring on the second Ta layer.

5. The method according to claim 4, wherein the first preliminary layer is formed to have a thickness of 0.5 Å to 10 Å.

6. The method according to claim 4, wherein the TaN layer and the second Ta layer are formed to have a thickness of 120 Å to 300 Å.

7. The method according to claim 4, wherein forming the first preliminary layer and forming the second preliminary layer each comprises maintaining a temperature of the semiconductor substance in the range of 100° C. to 500° C.

8. The method according to claim 4, wherein the metal wiring is made of copper.
